(19) United States
(12) Patent Application Publication
(10) Pub. No.: US 2007/0176607 A1
(43) Pub. Date: Aug. 2, 2007

(54) System and method for testing information handling system chassis shielding effectiveness

(76) Inventors: Raymond A. McCormick, Round Rock, TX (US); Jeffrey C. Hailey, Austin, TX (US); Richard N. Worley, Cedar Park, TX (US)

Correspondence Address: HAMILTON & TERRILE, LLP, P.O. BOX 203518, AUSTIN, TX, 78720, US

(21) Appl. No.: 11/341,272

(22) Filed: Jan. 27, 2006

(51) Int. Cl. G01R 27/28

(52) U.S. Cl. 324/627

(57) ABSTRACT

Information handling system chassis RF shielding is accurately characterized in a repeatable and rapid manner with a stirring device disposed within the chassis. An RF signal from an RF signal source disposed in the chassis emits a more homogeneous and uniform field due to movement of reflective surfaces of the stirring device within the chassis. For example, an RF receiver located outside the chassis measures the RF signal received from the chassis over one or more complete revolutions of the stirring device to provide improved uniformity of the RF field maximized or averaged over each revolution. The reflective surface is interchangeable to support testing of shielding for chassis of different sizes and rotate vertically and horizontally to average out both vertical and horizontal polarization.

### BACKGROUND OF THE INVENTION

1. Field of the Invention

The present invention relates in general to the field of information handling system chassis RF shielding, and more particularly to a system and method for testing information handling system chassis shielding effectiveness.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling system manufacturers generally attempt to configure information handling systems to have as much processing power as is economically available for a chassis of a given volume. Typically, as information handling system volume decreases, manufacturers have to use greater care in the distribution of processing components within the chassis so that desired operational constraints are met. One design constraint that often plays a primary role in the types of processing components available for a chassis and the distribution of the processing components in the chassis is the amount of radio frequency (RF) emissions from the chassis during operation of the processing components. Typically, in order to effectively design processing component layout for a chassis, the chassis is first evaluated for its effectiveness at shielding RF emissions. Shielding effectiveness varies with the types of materials used to build the chassis, the size and dimensions of the chassis, and the type of RF emissions involved. Shielding effectiveness is generally determined by placing an RF signal source inside the chassis and measuring the RF emissions with an antenna placed at predetermined distances from the chassis, such as one, three and ten meters. Acceptable levels of RF emissions are typically set by government regulations, such as those of the FCC.

One difficulty with obtaining accurate measurements of RF emissions from an information handling system chassis is that the level of emissions will often vary dependent upon the position of the RF signal source within the chassis. Thus, during RF emission testing the RF signal source is typically moved about to different positions within the chassis. To accomplish this, a test engineer typically has to open the chassis, move the RF signal source to a new location, close the chassis and re-measure the RF emissions outside the chassis. This process tends to be time consuming, especially with a smaller-sized chassis, such as a 1U chassis, which increases the difficulty of manually manipulating the position of the RF signal source. Further, recent developments have increased the number of frequencies that are subject to test by government regulations, such as CISPR updates and new requirements like cell phone immunity. Also, effective RF emission measurements are now often needed at higher frequencies since higher-speed technologies like PCIe, SAS and FBM operate at higher frequencies that generate higher frequency emissions.

### SUMMARY OF THE INVENTION

Therefore a need has arisen for a system and method which provides a homogeneous RF signal source within an information handling system chassis to test chassis shielding.

In accordance with the present invention, a system and method are provided which substantially reduce the disadvantages and problems associated with previous methods and systems for testing an information handling system chassis' RF shielding. A reflecting surface is moved within an information handling system chassis to provide a more uniform field from an RF signal source emitting an RF signal from within the chassis relative to an RF sensor disposed outside the chassis. Improved uniformity of a test signal emitted from within the chassis provides more rapid, accurate and repeatable characterization of the RF shielding provided by the chassis.

More specifically, an RF signal source and a stirring device having a moving reflective surface are disposed within the inside of an information handling system chassis under test. An RF receiver is disposed outside of the chassis at a predetermined distance from the chassis. The RF signal source emits a predetermined RF signal, such as a signal having a desired frequency and strength. The RF receiver detects the RF signal at the outside of the chassis to provide a characterization of the shielding of the chassis based on, for instance, the reception strength of the emitted RF signal a predetermined distance. Movement of the reflective surface within the chassis provides more uniform or homogeneous field maximized or averaged over one or more predetermined movement cycles. For example, the stirring device has a support shaft rotated about a vertical axis, the support shaft having reflective surfaces coupled to opposing ends so that each complete revolution about the vertical axis of the reflective surfaces changes the perturbations of the electromagnetic modes throughout the chassis to provide a consistent maximized or averaged field value. Further rotation of the reflective surfaces about a horizontal axis averages out vertical and horizontal polarizations. The reflective surfaces are removably coupled so that chassis with various dimensions have associated reflective surfaces of similar dimensions to fit within the chassis.

The present invention provides a number of important technical advantages. One example of an important technical advantage is that a uniform or homogeneous RF signal source is provided within an information handling system chassis for testing the shielding of the chassis. Use of a homogeneous RF signal source eliminates the need to move a signal source around within a chassis to ensure accurate test results measured outside of the chassis. Single RF source placement within the chassis reduces testing time by allowing a single measurement for a given RF signal. Test results are obtained quicker, are more accurate and are repeatable to provide improve RF shielding characterizations for a chassis under test.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a block diagram of an information handling system chassis under test for shielding characteristics;

FIG. 2 depicts an external view of an example of a stirring device; and

FIG. 3 depicts a schematic diagram of an example of a stirring device.

### DETAILED DESCRIPTION

A stirring device moving a reflective surface within an information handling system chassis provides a more uniform field for an RF source within the chassis, providing more accurate and repeatable tests of the shielding characteristics of the chassis. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

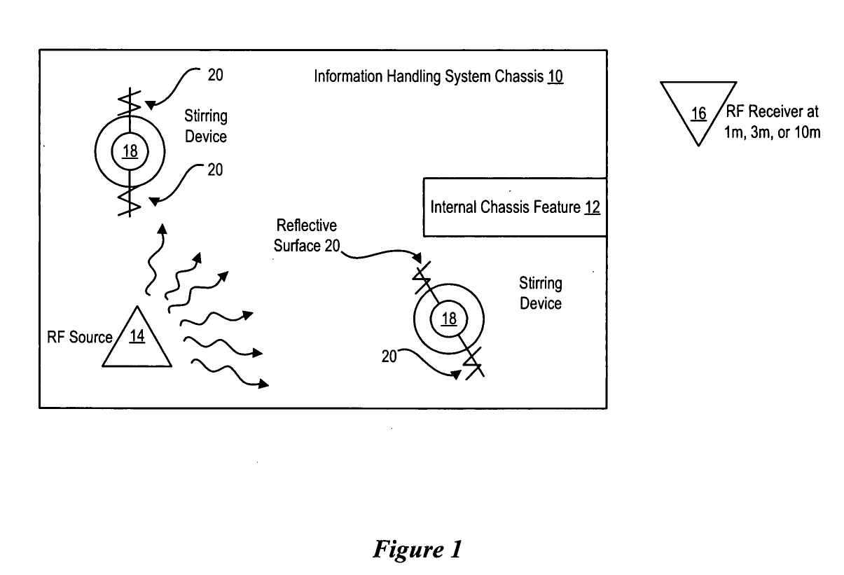

Referring now to FIG. 1, a block diagram depicts an information handling system chassis 10 under test for shielding characteristics. Chassis 10 typically has a rectangular box shape fabricated from sheet metal, although variations in shapes, dimensions and materials are common. Often, chassis 10 includes internal features 12 that are disposed to support the various processing components of an information handling system, such as the motherboard, CPU, chipset, memory and drives typically used to build an information handling system. Variations in size, dimensions, material, internal features and other factors impact the effectiveness of chassis 10 at shielding RF emissions generated by the processing components. Shielding effectiveness effects chassis design since RF signals generated by processing components operating within chassis 10 cannot exceed defined thresholds at predetermined distances from chassis 10, such as one, three or ten meters. In order to design an information handling system that operates within such constraints, the effectiveness of chassis 10 at shielding of RF signals is determined with test RF signals. Accurate chassis shielding testing reduces the risk that inadvertent excess levels of RF emissions will occur during operation of the system and also reduces production costs by limiting the need to add excess shielding as a cushion for inaccurate shielding tests.

To obtain accurate and repeatable chassis shielding characteristics, an RF source 14, such as a comb generator, transmits a predetermined RF signal from within chassis 10, and an RF receiver 16 receives the RF signal at a predetermined distance outside of chassis 10. Analysis of the difference between the transmitted and received RF signals provides a determination of the shielding effectiveness of chassis 10. Stirring devices 18 disposed within the inside of chassis 10 improve the accuracy of the shielding effectiveness determination by improving the uniformity of the RF signal throughout chassis 10. Stirring devices 18 have reflecting surfaces 20 that reflect the RF signal, such as metallic sheets. Reflecting surfaces 20 are rotated within chassis 10 to change the perturbations of the electromagnetic modes throughout the chassis, resulting in a homogeneous or uniform field when maximized or averaged over a complete revolution of reflecting surface 20. For example, the RF signal energy received at RF receiver 16 is analyzed over the time taken by stirring device 18 to complete a revolution or plural complete revolutions so that the impact of the location of RF source 14 is minimized by the more even distribution of the RF signal throughout chassis 10.

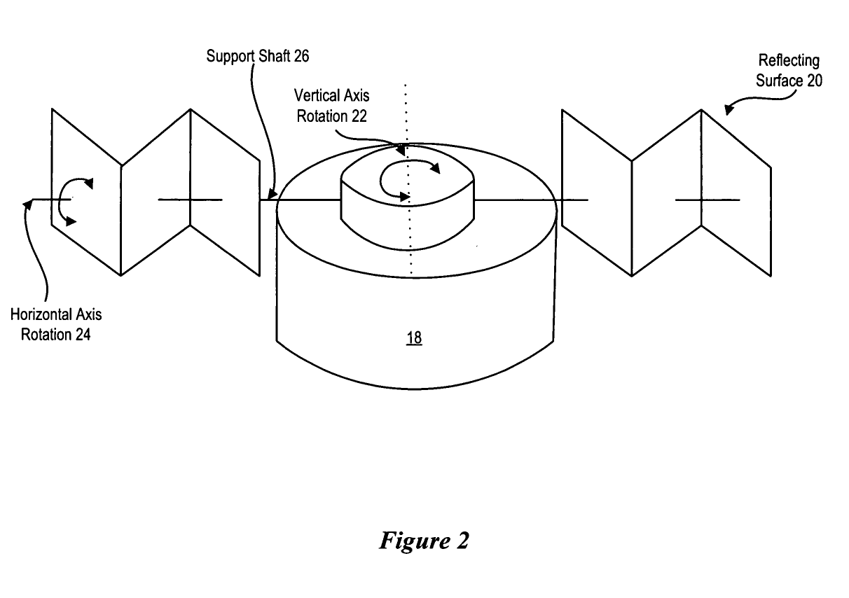

Referring now to FIG. 2, an external view depicts an example of a stirring device 18 for test of an information handling system's shielding characteristics. Stirring device 18 rotates reflecting surfaces 20 about a vertical axis as depicted by arrow 22 and rotates reflecting surfaces 20 about a horizontal axis as depicted by arrow 24. Rotation about both horizontal and vertical axes provides an improved RF signal field in both horizontal and vertical polarization. Rotation about each axis is independently variable in rate so that electromagnetic modes do not line-up. For example, multiple revolutions about horizontal axis 24 are performed for each revolution about vertical axis 22 with the relationship of the rotation rates varied based on the frequency of the RF signal under test. As depicted by FIG. 2, reflecting surfaces 20 are a matching pair of accordion-shaped metallic sheets coupled to opposing ends of a support shaft 26. Reflecting surfaces 20 are removable from support shaft 26 so that different sized reflecting surfaces may be used for different sized chassis 10. For instance, a small-dimensioned chassis, such as a 1U chassis, will have a matching pair of reflecting surfaces 20 that have dimensions shaped to fit in the chassis while larger chassis with greater dimensions will have matching pairs of reflecting surfaces 20 with greater dimensions. In alternative embodiments, the shape and dimensions of reflecting surfaces 20 may vary based on the type of chassis under test, the type of RF signal emitted within the chassis, and other factors to provide desired test conditions.

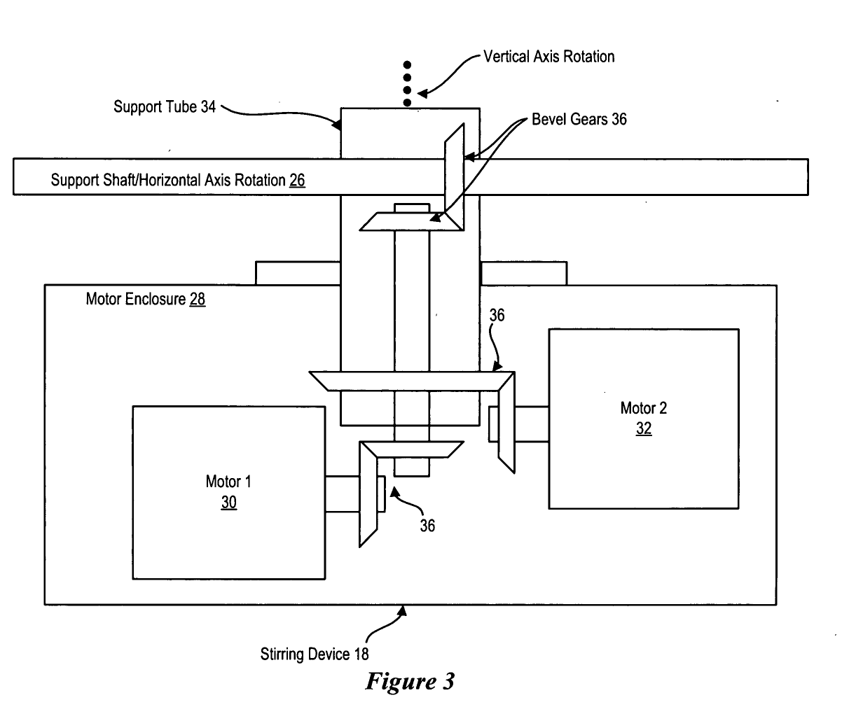

Referring now to FIG. 3, a schematic diagram depicts an example of a stirring device 18 for test of an information handling system chassis' shielding characteristics. A motor enclosure 28 contains a first motor 30 for driving horizontal rotation about support shaft 26 and a second motor 32 for driving vertical rotation about a support tube 34. Beveled drive gears 36 disposed in and along support tube 34 translate motion from motors 30 and 32 into rotation about the vertical and horizontal axes. Motor enclosure 28 has shielding to limit RF emissions from motors 30 and 32 into a chassis under test. The use of separate motors for horizontal and vertical rotation allows rotation rates about each axis to be independently set so that test engineers can use experimentation to determine optimal rotation rates for use in test. For example, an optimal rotation rate is determined by testing to see the rate that provides the most repeatable results. Reduced variations is the characterization of chassis shielding allows more precise design of the chassis for achieving desired shielding under operational conditions.

Although the present invention has been described in detail, it should be understood that various changes, substitutions and alterations can be made hereto without departing from the spirit and scope of the invention as defined by the appended claims.

1. A system for testing information handling system chassis shielding, the system comprising:
an information handling system chassis having an inside and an outside, the inside sized to contain information handling system processing components;
an RF signal source disposed inside the chassis and operable to output an RF signal inside the chassis;
an RF receiver disposed outside the chassis and operable to detect the RF signal outside the chassis to determine RF shielding associated with the chassis; and
a stirring device disposed inside the chassis and having a moving reflective surface operable to distribute RF signals from the RF signal source through the chassis to the RF receiver.

2. The system of claim 1 further comprising plural interchangeable reflective surfaces, each reflective surface operable to removably couple to the stirring device, each reflective surface having height and width dimensions sized to fit in an associated chassis.

3. The system of claim 1 wherein the stirring device moving reflective surface moves about a horizontal axis and a vertical axis.

4. The system of Claim of claim 1 further comprising plural stirring devices disposed inside the chassis.

5. The system of claim 1 wherein the stirring device comprises:
a shaft operable to support the moving reflective surface; and
a motor coupled to the shaft, the motor operable to rotate the shaft about a vertical axis to provide movement to the moving reflective surface.

6. The system of claim 5 wherein the stirring device further comprises a second motor coupled to the shaft, the second motor operable to rotate the shaft about a horizontal axis to provide movement to the moving reflective surface.

7. The system of claim 6 wherein the rotation about the vertical axis has a first rate and the rotation about the horizontal axis has a second rate independent of the first rate.

8. The system of claim 5 wherein the RF receiver determines RF shielding associated with the chassis based on one or more complete rotations of the moving reflective surface about the vertical axis.

9. The system of claim 1 wherein the RF signal source comprises a comb generator.

10. A method for characterizing the RF shielding of an information handling system chassis, the method comprising:
emitting an RF signal from within the chassis;
moving a reflective surface in a predetermined pattern within the chassis to reflect the RF signal; and
measuring the RF signal at a predetermined distance from the chassis to determine the shielding characteristics of the chassis.

11. The method of claim 10 wherein the predetermined pattern provides a generally uniform field about the chassis.

12. The method of claim 10 wherein moving a reflective surface further comprises rotating the reflective surface about a vertical axis and measuring the RF signal further comprises measuring the RF signal over one or more complete revolutions of the reflective surface.

13. The method of claim 10 wherein moving a reflective surface further comprises rotating the reflective surface about a horizontal axis and measuring the RF signal further comprises measuring the RF signal over one or more complete revolutions of the reflective surface.

14. The method of claim 10 wherein moving a reflective surface further comprises rotating the reflective surface simultaneously about a vertical axis and a horizontal axis.

15. The method of claim 10 wherein moving a reflective surface further comprises:
moving a first reflective surface at a first position within the chassis; and
moving a second reflective surface at a second position within the chassis.

16. The method of claim 10 further comprising:
selecting a reflective surface from a plurality of reflective surfaces, the selected reflective surface having dimensions associated with dimensions of the chassis;
coupling the reflective surface to a stirring device;
disposing the stirring device in the chassis; and
activating the stirring device to move the reflective surface.

17. A stirring device for determining information handling system chassis shielding characteristics, the stirring device comprising:
a motor operable to provide rotational motion;
a support shaft having first and second ends disposed along a horizontal axis, the support shaft coupled to the motor to accept the rotational motion about a vertical axis;
plural reflective surfaces, each reflective surface sized to fit in a predetermined information handling system chassis, the reflective surfaces removably coupleable to the support shaft to adapt to a selected of plural information handling system chassis sizes.

18. The stirring device of claim 17 wherein the reflective surfaces comprise matched pairs associated with each of plural information handling system chassis sizes, a first of the matched pairs coupling to shaft first end, the second of the matched pairs coupled to the shaft second end.

19. The stirring device of claim 17 wherein the support shaft is coupled to the motor to further accept rotational motion about a horizontal axis.

20. The stirring device of claim 19 wherein the motor further comprises a first motor operable to provide rotational motion about the vertical axis and a second motor operable to provide rotational motion about the horizontal axis.
